(19) United States
(12) Patent Application Publication
(10) Pub. No.: US 2025/0341585 A1
(43) Pub. Date: Nov. 6, 2025

(54) BATTERY STATE HEALTH ESTIMATION USING CURRENT CHARACTERISTICS AT A CONSTANT VOLTAGE

(71) Applicant: GM GLOBAL TECHNOLOGY OPERATIONS LLC, DETROIT, MI (US)

(72) Inventors: Rasoul Salehi, Ann Arbor, MI (US); Xinyu Du, Oakland Township, MI (US); Shengbing Jiang, Rochester Hills, MI (US)

(21) Appl. No.: 18/651,967

(22) Filed: May 1, 2024

(51) Int. Cl. G01R 31/3842; G01R 19/12; G01R 31/367; G01R 31/392; G01R 31/396

(52) U.S. Cl. CPC G01R 31/3842; G01R 19/12; G01R 31/367; G01R 31/392; G01R 31/396

(57) ABSTRACT

Examples described herein provide a method that includes detecting a start of a constant voltage operation phase of a battery of a vehicle. The method further includes collecting current information and voltage information about the battery. The method further includes monitoring a health indicator for the battery based at least in part on the current information. The method further includes determining whether the battery is in a healthy state or a fault state by determining whether the health indicator is within an acceptable range. The method further includes, responsive to determining that the battery is in the fault state, implementing a corrective action for the battery.

The subject disclosure relates to vehicles, and in particular to battery state health estimation using current characteristics at a constant voltage.

Modern vehicles (e.g., a car, a motorcycle, a boat, or any other type of automobile) may be equipped with one or more batteries to provide electrical power to various systems of the vehicle. For example, an electric vehicle may include one or more batteries to store and provide electrical power to one or more electric motors, which provide propulsion to the vehicle. This configuration of vehicle is referred to as a battery electric vehicle (BEV). Other types of vehicles may also be equipped with batteries, such as vehicles with combustion engines, hybrid-electric vehicles, and/or the like, including combinations and/or multiples thereof. Other examples of components of vehicles that can use electric power stored in a battery include, but are not limited to, pumps, actuators, sensors, processing systems, displays, climate control systems, infotainment systems, engine control units, and/or the like, including combinations and/or multiples thereof.

### SUMMARY

In one embodiment, a method is provided. The method includes detecting a start of a constant voltage operation phase of a battery of a vehicle. The method further includes collecting current information and voltage information about the battery. The method further includes monitoring a health indicator for the battery based at least in part on the current information. The method further includes determining whether the battery is in a healthy state or a fault state by determining whether the health indicator is within an acceptable range. The method further includes, responsive to determining that the battery is in the fault state, implementing a corrective action for the battery.

In addition to one or more of the features described herein, or as an alternative, further embodiments of the method include that the health indicator is based at least in part on a slope of a line fit to a natural log of current of the battery, indicated by the current information.

In addition to one or more of the features described herein, or as an alternative, further embodiments of the method include that the health indicator is based at least in part on a coefficient of determination of a line fit to a natural log of current of the battery, indicated by the current information.

In addition to one or more of the features described herein, or as an alternative, further embodiments of the method include that collecting the current information and the voltage information about the battery is performed while the battery is in the constant voltage operation phase.

In addition to one or more of the features described herein, or as an alternative, further embodiments of the method include that the collecting terminates responsive to determining that current of the battery, indicated by the current information, reaches a minimum current level.

In addition to one or more of the features described herein, or as an alternative, further embodiments of the method include that the corrective action is at least one of repairing the battery, replacing the battery, correcting an electrolyte leak in the battery, redesigning the battery, and adjusting a manufacturing process for manufacturing other batteries.

In addition to one or more of the features described herein, or as an alternative, further embodiments of the method include that the fault state is a loss of active material fault.

In addition to one or more of the features described herein, or as an alternative, further embodiments of the method include that the fault state is an electrolyte fault.

In another embodiment, a vehicle is provided. The vehicle includes a battery and a processing system. The processing system includes a memory having computer readable instructions. The processing system further includes a processing device for executing the computer readable instructions, the computer readable instructions controlling the processing device to perform operations. The operations include detecting a start of a constant voltage operation phase of the battery of the vehicle. The operations further include collecting current information and voltage information about the battery. The operations further include monitoring a health indicator for the battery based at least in part on the current information. The operations further include determining whether the battery is in a healthy state or a fault state by determining whether the health indicator is within an acceptable range. The operations further include, responsive to determining that the battery is in the fault state, implementing a corrective action for the battery.

In addition to one or more of the features described herein, or as an alternative, further embodiments of the vehicle include that the health indicator is based at least in part on a slope of a line fit to a natural log of current of the battery, indicated by the current information.

In addition to one or more of the features described herein, or as an alternative, further embodiments of the vehicle include that the health indicator is based at least in part on a coefficient of determination of a line fit to a natural log of current of the battery, indicated by the current information.

In addition to one or more of the features described herein, or as an alternative, further embodiments of the vehicle include that collecting the current information and the voltage information about the battery is performed while the battery is in the constant voltage operation phase.

In addition to one or more of the features described herein, or as an alternative, further embodiments of the vehicle include that the collecting terminates responsive to determining that current of the battery, indicated by the current information, reaches a minimum current level.

In addition to one or more of the features described herein, or as an alternative, further embodiments of the vehicle include that the corrective action is at least one of repairing the battery, replacing the battery, correcting an electrolyte leak in the battery, redesigning the battery, and adjusting a manufacturing process for manufacturing other batteries.

In addition to one or more of the features described herein, or as an alternative, further embodiments of the vehicle include that the fault state is a loss of active material fault.

In addition to one or more of the features described herein, or as an alternative, further embodiments of the vehicle include that the fault state is an electrolyte fault.

In another embodiment a computer program product is provided. The computer program product includes a computer readable storage medium having program instructions embodied therewith, the program instructions executable by at least one processor to cause the at least one processor to perform operations. The operations include detecting a start of a constant voltage operation phase of a battery of a vehicle. The operations further include collecting current information and voltage information about the battery. The operations further include monitoring a health indicator for the battery based at least in part on the current information. The operations further include determining whether the battery is in a healthy state or a fault state by determining whether the health indicator is within an acceptable range. The operations further include, responsive to determining that the battery is in the fault state, implementing a corrective action for the battery.

In addition to one or more of the features described herein, or as an alternative, further embodiments of the computer program product include that the health indicator is based at least in part on a slope of a line fit to a natural log of current of the battery, indicated by the current information.

In addition to one or more of the features described herein, or as an alternative, further embodiments of the computer program product include that the health indicator is based at least in part on a coefficient of determination of a line fit to a natural log of current of the battery, indicated by the current information.

In addition to one or more of the features described herein, or as an alternative, further embodiments of the computer program product include that the fault state is one of a loss of active material fault or an electrolyte fault.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is an illustration of a vehicle having a processing system for performing battery state health estimation using current characteristics at a constant voltage according to one or more embodiments;

FIG. 2 is a block diagram of the processing system of FIG. 1 for performing battery state health estimation using current characteristics at a constant voltage according to one or more embodiments;

FIG. 3A is a flow diagram of a method for performing battery state health estimation using current characteristics at a constant voltage according to one or more embodiments;

FIG. 3B is a circuit diagram of an equivalent circuit model according to one or more embodiments;

FIG. 4A shows graphs of a first fault mode according to one or more embodiments;

FIG. 4B shows graphs of a second fault mode according to one or more embodiments;

FIG. 5 is a flow diagram of a method for performing battery state health estimation using current characteristics at a constant voltage according to one or more embodiments; and

FIG. 6 is a block diagram of a processing system for implementing one or more embodiments described herein.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

One or more embodiments described herein relates to battery state health estimation (such as of a battery of a vehicle) using current characteristics at a constant voltage. For example, current profile characteristics and statistics of the battery can be used as battery aging and health indicators. One or more embodiments provide for monitoring a battery state of the health of a battery (e.g., a battery of a vehicle) using functions that characterize the current profile and the current's rate of change during constant voltage (CV) operation of battery cells (assembled or single). Such embodiments enable battery fault detection. By detecting battery faults, vehicle operation and function is improved because faulty batteries can be detected and repaired or replaced in a more efficient manner.

Batteries, such as batteries in vehicles, can degrade over time as a result of natural aging, defects or abnormalities during manufacturing, operation conditions, environmental conditions, and/or the like, including combinations and/or multiples thereof. For example, batteries of vehicles operating in very hot or very cold climates may degrade more quickly than batteries of vehicles operating in more moderate climates. It is therefore desirable to monitor the health of batteries of vehicles to determine when to service and/or replace the batteries. Some approaches to monitoring battery health include using a voltage-based approach. A voltage-based approach evaluates the health of the battery during a constant current operation, where the voltage varies. However, such approaches are ineffective at constant voltage operation. Moreover, such approaches are unable to detect certain battery faults because observability is very low at constant current phases of a charging profile. For example, it may not be possible to detect an electrolyte fault during constant current states.

One or more embodiments described herein address these and other shortcomings by providing for battery state health estimation (such as of a battery of a vehicle) using current characteristics at a constant voltage. Embodiments described herein apply derived equations for expected shape of the current profile during constant voltage phase and use a function of current at constant voltage to estimate battery health and detect faults, such as an electrolyte fault, that are not observable during constant current states.

It should be appreciated that the functioning of a vehicle implementing one or more of the embodiments described herein is improved. For example, as described, one or more embodiments can be used to detect faults, such as an electrolyte fault, that are not observable during constant current states. By implementing battery state health estimation (such as of a battery of a vehicle) using current characteristics at a constant voltage (as described herein), a vehicle is improved because such faults can be detected and corrected whereas such faults would be undetected otherwise. As a result, corrective actions, such as maintenance, repair, or replacement, can be implemented, and the vehicle is thereby improved. Moreover, manufacturing of batteries can be approved because one or more embodiments described herein can be applied during end-of-the-line of the cell manufacturing process for the battery to detect faults and/or to redesign batteries where premature aging is determined using data aggregated from multiple batteries/vehicles.

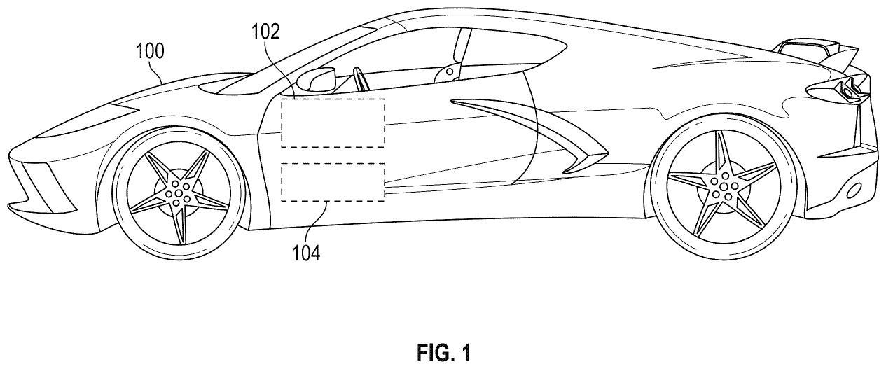

FIG. 1 is an illustration of a vehicle 100 having a processing system 102 for performing battery state health estimation using current characteristics at a constant voltage according to one or more embodiments. The vehicle 100 can be a car, a truck, a van, a bus, a motorcycle, a boat, or any other type of automobile. According to an embodiment, the vehicle 100 includes an internal combustion engine fueled by gasoline, diesel, or the like. According to another embodiment, the vehicle 100 is a hybrid electric vehicle partially or wholly powered by electrical power. According to another embodiment, the vehicle 100 is an electric vehicle powered by electrical power. According to one or more embodiments, the vehicle 100 is an autonomous or semi-autonomous vehicle. An autonomous vehicle is a vehicle that has self-driving capabilities.

According to one or more embodiments, the vehicle 100 includes the processing system 102 and a battery 104. The battery 104 represents one or multiple batteries and/or battery systems. A battery system can include one or more batteries and one or more controllers to manage the batteries. The battery 104 stores electrical power, which can be used to power systems and/or components of the vehicle 100, such as electric motors, pumps, actuators, sensors, processing systems, displays, climate control systems, infotainment systems, engine control units, and/or the like, including combinations and/or multiples thereof. As the battery 104 is used, over time the battery can degrade, causing it to be less efficient. For example, the battery 104 may store less electrical power over time as compared to when the battery was new. According to various embodiments, the battery 104 can be a single battery cell or a pack/module of cells connected in a mixed configuration of parallel and series. It should be appreciated that the embodiments described herein can be applied to any suitable chemistry used in batteries.

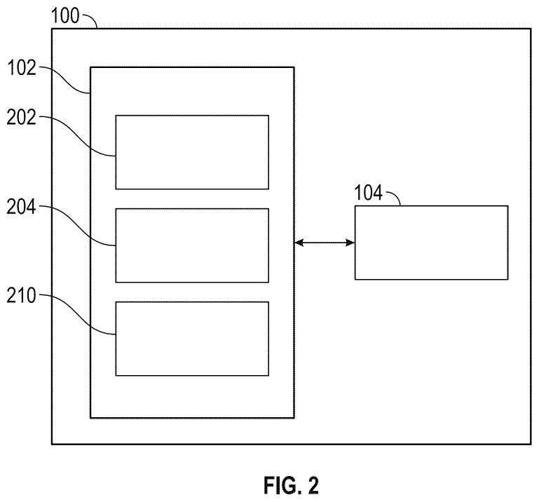

The processing system 102 can use information collected from the battery 104 to perform battery state health estimation using current characteristics at a constant voltage. Further features of the processing system 102 are now described with reference to FIG. 2.

Particularly, FIG. 2 is a block diagram of the processing system 102 of FIG. 1 for performing battery state health estimation using current characteristics at a constant voltage according to one or more embodiments. The processing system 102 includes a processing device 202, a memory 204, and a battery state health estimation engine 210. It should be appreciated that the processing system 102 can be any device suitable for performing battery state health estimation. For example, the processing system 102 can be a device implemented in or otherwise associated with the vehicle 100. As another example, the processing system 102 can be a smartphone, tablet computer, laptop computer, desktop computer, wearable computing device, and/or the like, including combinations and/or multiples thereof.

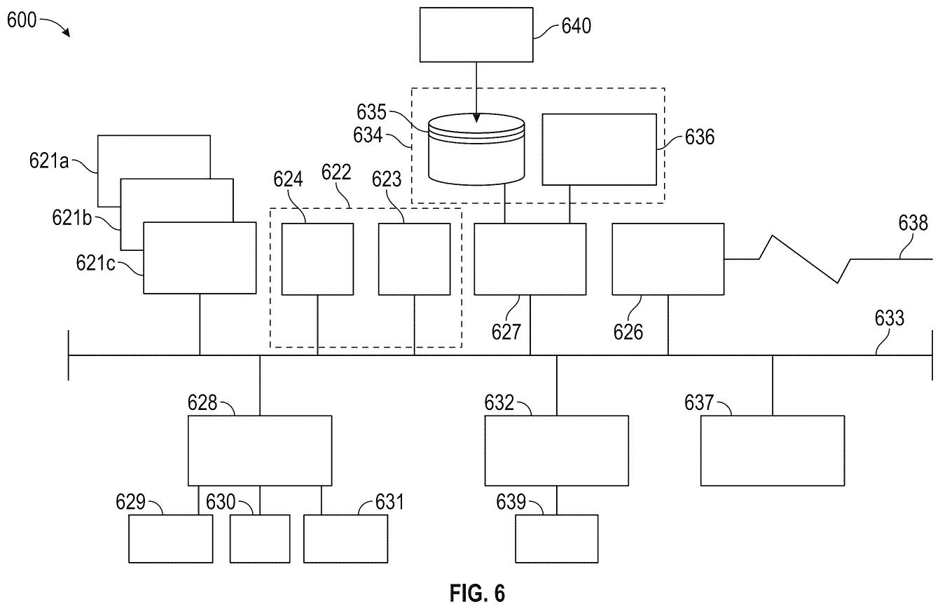

The processing device 202 is any suitable processing circuitry for processing data and/or instructions. The processing device 202 is an example of one or more of the processing devices 621 of FIG. 6, as described in more detail herein.

The memory 204 is any suitable device for storing data and/or instructions. The memory 204 is an example of one or more of the system memory 622, the random access memory 623, and/or the read-only memory 624 of FIG. 6, as described in more detail herein.

The battery state health estimation engine 210 performs battery state health estimation using current characteristics at a constant voltage, as described in more detail herein.

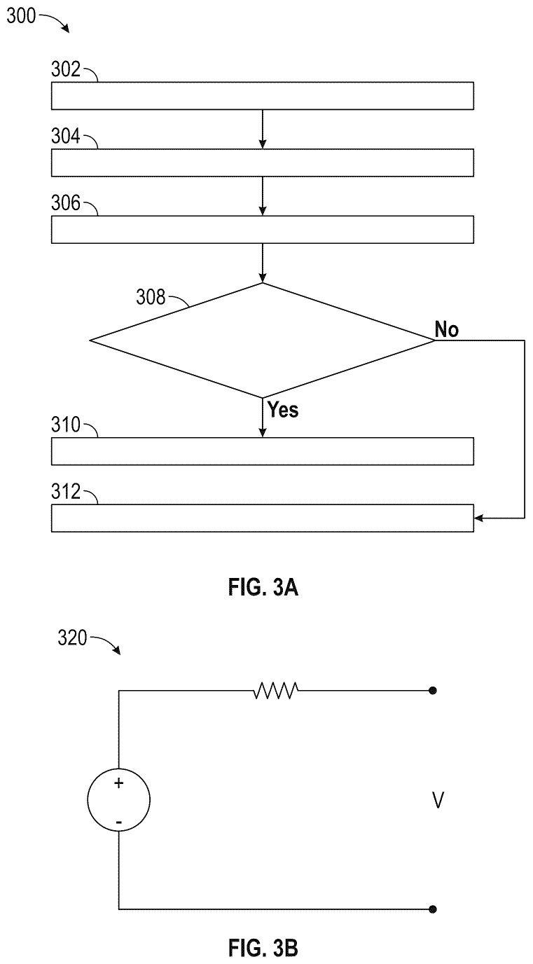

Further aspects and features of the battery state health estimation engine 210 are described herein with respect to FIGS. 3, 4A, 4B, and 5.

The various components, modules, engines, etc. described regarding FIG. 2 (e.g., the battery state health estimation engine 210) can be implemented as instructions stored on a computer-readable storage medium, as hardware modules, as special-purpose hardware (e.g., application specific hardware, application specific integrated circuits (ASICs), application specific special processors (ASSPs), field programmable gate arrays (FPGAs), as embedded controllers, hardwired circuitry, etc.), or as some combination or combinations of these. According to aspects of the present disclosure, the engine(s) described herein can be a combination of hardware and programming. The programming can be processor executable instructions stored on a tangible memory, and the hardware can include the processing device 202 for executing those instructions. Thus a system memory (e.g., memory 204) can store program instructions that when executed by the processing device 202 implement the engines described herein. Other engines can also be utilized to include other features and functionality described in other examples herein.

FIG. 3A is a flow diagram of a method 300 for performing battery state health estimation using current characteristics at a constant voltage according to one or more embodiments. The method 300 can be implemented using any suitable system or device. For example, the method 300 can be implemented using the processing system 102 of FIGS. 1 and 2, by the processing system 600 of FIG. 6, and/or the like, including combinations and/or multiples thereof. The method 300 is now described with reference to FIGS. 1 and 2 but is not so limited.

At block 302, the processing system 102 (e.g., using the battery state health estimation engine 210) detects the start of a constant voltage operation phase (e.g., constant voltage charging or discharging). The constant voltage operation phase can be detected by monitoring the voltage supplied to the battery 104 during charging (e.g., while the battery 104 is connected to a charging station or other source of electrical power, such as electrical power generated by an electrical motor of the vehicle during braking) or during discharging. The voltage can be considered constant, for example, if the voltage is within a certain range for a period of time (e.g., within +/−0.5 volts of 240 volts for 5 seconds, within +/−0.01 volts of 4.2 volts for 7 seconds, and/or the like, including combinations and/or multiples thereof). Other ranges and/or other periods of time can be implemented in various embodiments.

At block 304, the processing system 102 (e.g., using the battery state health estimation engine 210) collects current information and voltage information about the battery 104 while the battery 104 is in the constant voltage operation phase. The constant voltage operation phase may terminate, for example, when the current reaches a minimum current level. Thus, the processing system 102 collects the current and voltage for the battery 104 until the current reaches the minimum current level.

At block 306, the processing system 102 (e.g., using the battery state health estimation engine 210) monitors one or more health indicators based on the current information collected at block 304. Health indicators represent the relation between voltage of the battery cell/module/pack (e.g., the battery 104) and the current of the battery 104 using physics-based model equations, which are now described in more detail. Different statistical approaches can be applied to the following set of equations to determine various health indicators, such as the slope of a line fit to the natural log of the current (Ln(I)), the coefficient of determination (R²) of the line fit to the natural log of the current (Ln(I)), and/or the like, including combinations and/or multiples thereof. According to one or more embodiments, the current profile for the battery 104 follows the natural log (Ln) function during constant voltage charging/discharging. This behavior provides for using a health indicator, such as a linear regression, to monitor battery health during constant voltage charging/discharging.

More particularly, current can be modeled during constant voltage operation using the following equations. The electrochemical battery single particle model is simplified in this section to calculate the expected profile of the cell current during constant voltage operation. The cell voltage is the difference between the positive (cathode) Φₛ⁺ of and negative (anode) φₛ⁻ solid potentials:

$${V = {Φ}_{s}^{+} {\vert}_{x = L} - {Φ}_{s}^{-} \vert}_{x = 0} . \qquad ( 1 )$$

Each electrode potential is calculated from its overpotential (η), the electrolyte potential (e), and the electrode open-circuit potential (U):

$${Φ}_{s}^{+} ( x , t ) = {η}^{\pm } + {Φ}_{e}^{\pm } + {U}^{\pm } + {FR}_{eff} {J}^{\pm } \qquad ( 2 )$$

where J is the molar particle ion flux, F is the Faraday's constant, and R_{eff} is the effective film resistance. In equation (2), the “+” sign refers to the positive and the “−” sign refers to the negative electrode. A simplification method is presented here to linearize terms on the right-hand side of equation (2). Assuming I(t)/2a⁺L⁺*i₀⁺(t)<1, where I(t) is the cell charge per area, the cell overpotential could be related to the cell current as:

$${η}^{+} - {η}^{-} = \frac{RT}{α F} [ {sinh}^{- 1} ( \frac{I ( t )}{2 {a}^{+} {L}^{+} * {i}_{0}^{+} ( t )} ) - {sinh}^{- 1} ( \frac{- I ( t )}{2 {a}^{-} {L}^{-} * {i}_{0}^{-} ( t )} ) ] = {ε}_{1} ( t ) I ( t ) \qquad ( 3 )$$

With i₀ the exchange current density, L is the thickness of each electrode, and a is Active surface area per electrode unit volume. The parameter ε₁ is assumed to capture all constant and time varying terms that linearly correlate the current I flux to the cell overpotential. Similarly, the electrolyte potential is linearized as:

$${Φ}_{s}^{+} - {ϕ}_{s}^{+} = \frac{{L}^{+} + 2 {L}^{sep} + {L}^{-}}{2 κ} I ( t ) = {ε}_{2} ( t ) I ( t ) \qquad ( 4 )$$

with κ as the ionic conductivity of the electrolyte and L^{sep} the thickness of the separator. The molar flux J can be correlated with the surface current through:

$${FR}_{eff} J = \frac{{Fr}_{eff} J}{\frac{( 3 {L}_{electrode} * ϵ )}{{R}_{shape}}} = {ε}_{3} ( t ) I ( t ) \qquad ( 5 )$$

with ϵ as the active material volume fraction and Rₛₚₕₑᵣₑ being the radius of the sphere assumed to represent the electrode in the single particle model. The open circuit potential, U, of each electrode is mainly a function of the electrode SOC (ignoring the other minor factors such as temperature) and could be linearized as a function of cell charge capacity Q using:

$${U}^{+} - {U}^{-} = {OCP}^{+} ( SOC ) - {OCP}^{-} ( SOC ) = {ε}_{4} ( t ) Q \qquad ( 6 )$$

Using equations (1)-(6), the linear cell voltage is calculated as a function of cell current and charge capacity:

$$V = {ε}_{1} I + {ε}_{2} I + {ε}_{3} + {ε}_{4} Q \qquad ( 7 )$$

Equation (7) represents an equivalent circuit battery model 320 as shown in FIG. 3B with a single resistance for the battery cell. Assuming the parameters ε₁, ε₂, ε₃, ε₄ are time invariant during the constant voltage operation, the derivative of voltage can be calculated as:

$$\begin{matrix}\dot{V} = ( {ε}_{1} + {ε}_{2} + {ε}_{3} ) \frac{dI}{dt} + {ε}_{4} \frac{dQ}{dt} \\ \frac{dQ}{dt} = {IA}_{eff}\end{matrix} \qquad ( 8 )$$

where A_{eff} is the cell effective area. Since the voltage is constant in constant voltage mode, then \dot{V}=0 and equation (8) simplifies to:

$$\frac{dI}{I} = - \frac{{ε}_{4} {A}_{eff}}{( {ε}_{1} + {ε}_{2} + {ε}_{3} )} dt \qquad ( 9 )$$

Integrating equation (9), the final correlation between the cell current and time during constant voltage operation is derived as:

$$ln ( I ) = - \frac{{ε}_{4} {A}_{eff}}{( {ε}_{1} + {ε}_{2} + {ε}_{3} )} t + ln ( I ( 0 ) ) \qquad ( 10 )$$

As equation (10) suggests, during the constant voltage phase, In(I) changes linearly in time t with slope α=−ε₄A_{eff}/(ε₁+ε₂+ε₃). The change(s) in the model parameters and/or the change to the slope m of the line are used as the health indicator according to one or more embodiments.

With continued reference to FIG. 3A, at block 308, At block 304, the processing system 102 (e.g., using the battery state health estimation engine 210) determines whether the health indicator is within an acceptable range. For example, the acceptable range can be bounded by a minimum health indicator value and a maximum health indicator value. Where the health indicator is a slope (m) of a line fit to a natural log of the current of the battery (indicated by the current information), the acceptable range can be defined by a minimum slope (mₘᵢₙ) and a maximum slope (mₘₐₓ). Where the health indicator is a coefficient of determination (R²) of a line fit to a natural log of current of the battery (indicated by the current information), the acceptable range can be defined by a minimum coefficient of determination (Rₘᵢₙ²) and a maximum coefficient of determination (Rₘᵢₙ²).

If it is determined that the health indicator is in an acceptable range (e.g., that the slope (m) is within the range bounded by the minimum slope (mₘᵢₙ) and the maximum slope (mₘₐₓ)) (block 308 “YES), the processing system 102 determines that the battery 104 is in a healthy state (block 310). However, if it is determined that the health indicator is not in an acceptable range (e.g., that the slope (m) is outside the range bounded by the minimum slope (mₘᵢₙ) and the maximum slope (mₘₐₓ)) (block 308 “NO”), the processing system 102 determines that the battery 104 is in a fault state (block 312). According to one or more embodiments, responsive to determining that the battery is in a fault state, the method 300 can include implementing a corrective action. Examples of corrective actions include repairing a battery, replacing a battery, correcting an electrolyte leak, redesigning a battery or adjusting a manufacturing process (e.g., based on data collected from multiple batteries/vehicles), and/or the like, including combinations and/or multiples thereof.

Additional processes also may be included, and it should be understood that the processes depicted in FIG. 3A represent illustrations, and that other processes may be added, or existing processes may be removed, modified, or rearranged without departing from the scope of the present disclosure. It should also be understood that the processes depicted in FIG. 3A may be implemented as programmatic instructions stored on a non-transitory computer-readable storage medium that, when executed by a processor (e.g., the processing device 202 of FIG. 2, the processor(s) 621 of FIG. 6, and/or the like, including combinations and/or multiples thereof) of a computing system (e.g., the processing system 102 of FIGS. 1 and 2, the processing system 600 of FIG. 6, and/or the like, including combinations and/or multiples thereof), cause the processor to perform the processes described herein.

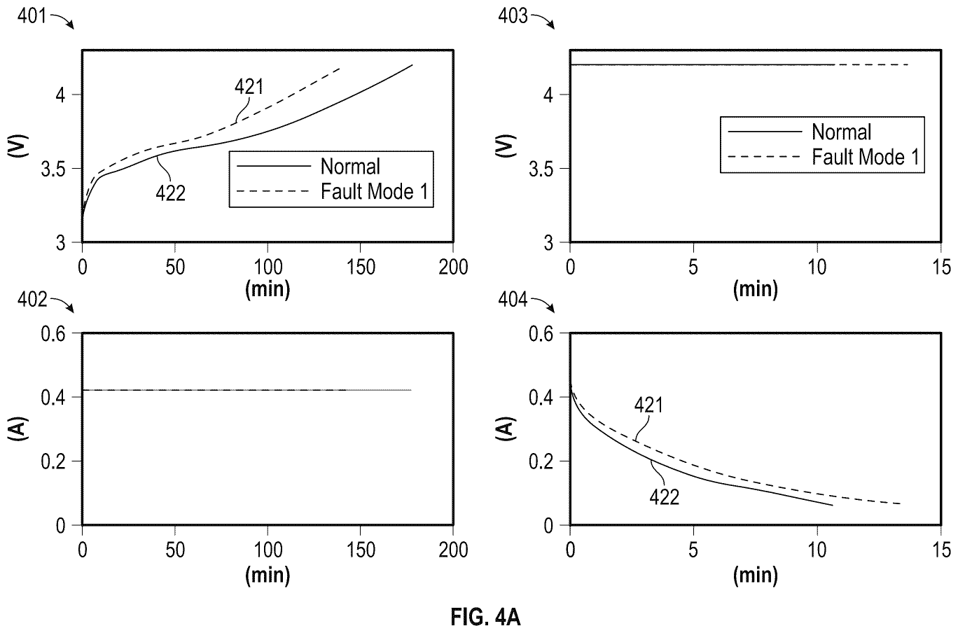

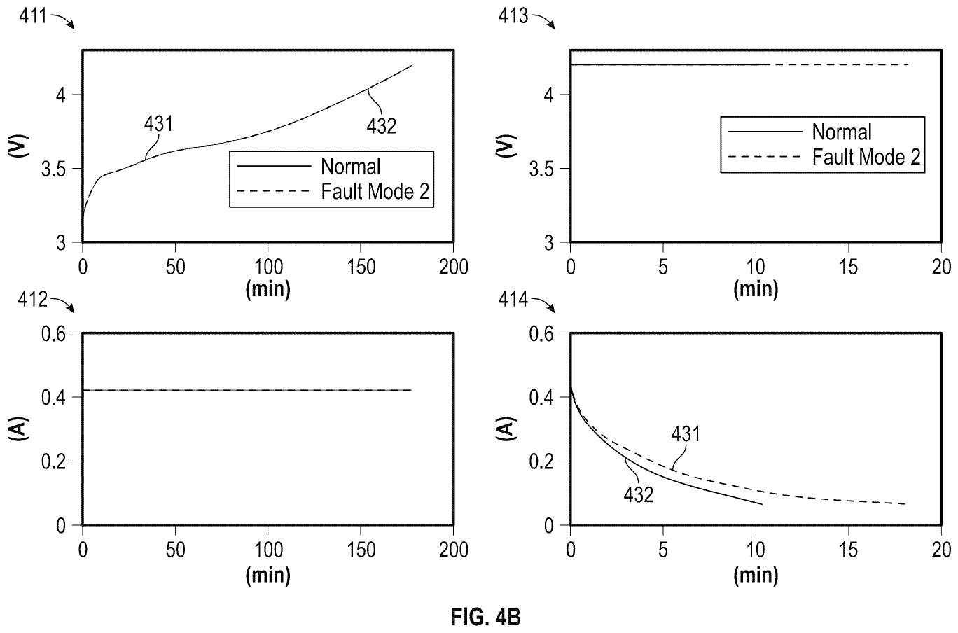

FIG. 4A shows graphs 401, 402, 403, 404 of a first fault mode according to one or more embodiments. In this example, the first fault mode is a loss of active material fault. The graphs 401 and 402 depict, respectively, the voltage (in volts) and current (in amps) over time (in minutes) during constant current charging, and the graphs 403 and 404 depict, respectively, the voltage (in volts) and current (in amps) over time (in minutes) during constant voltage charging. As can be seen by comparing the graphs 401 and 404, a loss of active material fault (e.g., fault mode 1 421) can be observed during constant current charging (graph 401) and during constant voltage charging (graph 403) as compared to a normal condition (normal 422). However, in some cases, some faults may not be evident during constant current charging, which is a reason to perform battery state health estimation using current characteristics at a constant voltage. For example, FIG. 4B shows a fault condition not detectable during constant current charging.

More particularly, FIG. 4B shows graphs 411, 412, 413, 414 of a second fault mode according to one or more embodiments. In this example, the second fault mode is an electrolyte fault. The graphs 411 and 412 depict, respectively, the voltage (in volts) and current (in amps) over time (in minutes) during constant current charging, and the graphs 413 and 414 depict, respectively, the voltage (in volts) and current (in amps) over time (in minutes) during constant voltage charging. As can be seen by comparing the graphs 411 and 414, the electrolyte fault (e.g., fault mode 2 431) is not evident during constant current charging (graph 411) but can be observed during constant voltage charging (graph 413) as compared to a normal condition (normal 432). Thus, by applying battery state health estimation using current characteristics at a constant voltage, battery faults that were otherwise undetectable can now be detected, thus improving vehicle functionality.

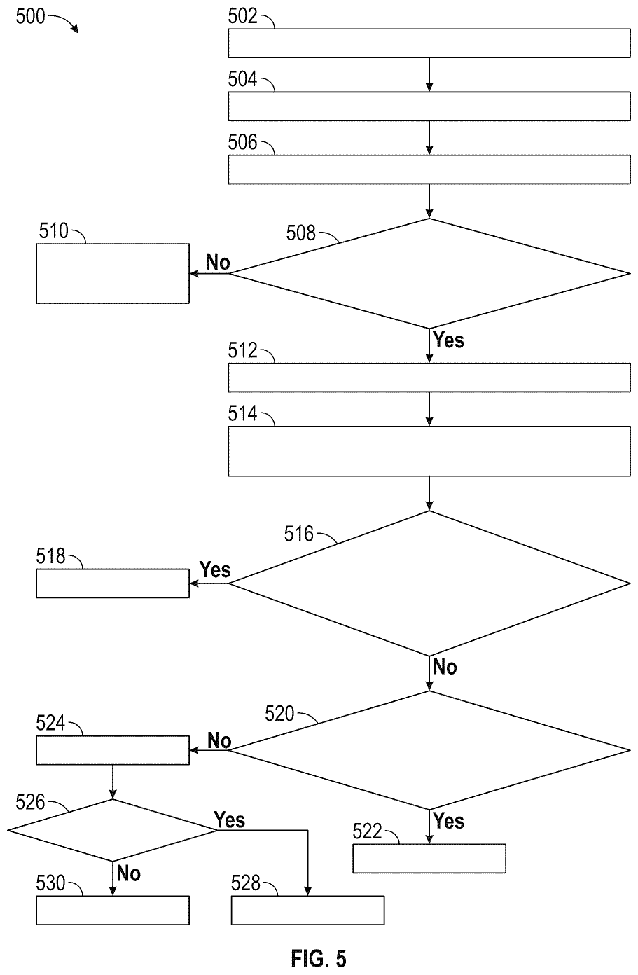

FIG. 5 is a flow diagram of a method 500 for performing battery state health estimation using current characteristics at a constant voltage according to one or more embodiments. The method 500 can be implemented using any suitable system or device. For example, the method 500 can be implemented using the processing system 102 of FIGS. 1 and 2, by the processing system 600 of FIG. 6, and/or the like, including combinations and/or multiples thereof. The method 500 is now described with reference to FIGS. 1 and 2 but is not so limited.

At block 502, the processing system 102 (e.g., using the battery state health estimation engine 210) detects the start of a constant voltage operation phase.

At block 504, the processing system 102 (e.g., using the battery state health estimation engine 210) collects current information and voltage information about the battery 104 while the battery 104 is in the constant voltage operation phase.

At block 506, the processing system 102 (e.g., using the battery state health estimation engine 210) calculates a voltage variance. The voltage variance is a measure of how far the actual voltage is from an expected/desired voltage (e.g., a voltage variance threshold). If the voltage variance remains less than the voltage variance threshold (block 508 “NO”), then the battery is not in a constant voltage operation (block 510). Otherwise (block 508 “YES”), the method 500 proceeds to block 512 and fits a line to the natural log of the current as described herein. The slope (m) of the line from block 512 is then calculated at block 514 along with the coefficient of determination (R²) for the line.

If the slope (m) of the line is within an acceptable range and the coefficient of determination (R²) for the line is greater than a minimum (block 516 “YES”), no fault is present (block 518). However, if either of the slope (m) of the line is outside an acceptable range and/or the coefficient of determination (R²) for the line is not greater than a minimum (block 516 “NO”), a fault may be present and the method 500 proceeds to block 520.

At block 520, it is determined whether the coefficient of determination (R²) for the line is less than the minimum. If so (block 520 “YES”), then a fault is probable (block 522). However, if it is determined that the coefficient of determination (R²) for the line is not less than the minimum, a fault is possible (block 524). To determine whether a fault exists, and what type of fault, the method 500 proceeds block 526 where the capacity drop of the battery 104 is observed. If the capacity of the battery 104 drops (e.g., by a certain amount or percentage, below a threshold, and/or the like, including combinations and/or multiples thereof) (block 526 “YES”), a loss of active material (LAM) fault is determined to have occurred (block 528). If no capacity drop is observed (block 526 “NO”), an electrolyte fault 530 is observed to have occurred.

Additional processes also may be included, and it should be understood that the processes depicted in FIG. 5 represent illustrations, and that other processes may be added, or existing processes may be removed, modified, or rearranged without departing from the scope of the present disclosure. It should also be understood that the processes depicted in FIG. 5 may be implemented as programmatic instructions stored on a non-transitory computer-readable storage medium that, when executed by a processor (e.g., the processing device 202 of FIG. 2, the processor(s) 621 of FIG. 6, and/or the like, including combinations and/or multiples thereof) of a computing system (e.g., the processing system 102 of FIGS. 1 and 2, the processing system 600 of FIG. 6, and/or the like, including combinations and/or multiples thereof), cause the processor to perform the processes described herein.

According to one or more embodiments, constant voltage phases can be detected during both charge and discharge sections for each cell group of the battery 104 and the proposed health indicator(s) can be calculated based on the current profile and compared with different cell groups that have operated in a similar operating conditions.

According to one or more embodiments, the health indicator can be calculated during cell operation on a vehicle or when the battery 104 is detached from the vehicle (such as end-of-the-line of the cell manufacturing process).

According to one or more embodiments, the current-based health indicator(s) can be used to determine the aging level of the battery 104 and if the battery 104 abnormally aged over the usage of the battery 104 on vehicle or due to some abuse of the cell (e.g., operation of the cell at high temperature).

According to one or more embodiments, the health indicator(s) be used along with other health indicators to isolate a fault. For example, the electrolyte fault can be isolated from the LAM by using the capacity fade because LAM ends with capacity fade, whereas electrolyte fault does not cause capacity fade.

It is understood that one or more embodiments described herein is capable of being implemented in conjunction with any other type of computing environment now known or later developed. For example, FIG. 6 depicts a block diagram of a processing system 600 for implementing the techniques described herein. In accordance with one or more embodiments described herein, the processing system 600 is an example of a cloud computing node of a cloud computing environment. In examples, processing system 600 has one or more central processing units (referred to also as “processors” or “processing resources” or “processing devices”) 621a, 621b, 621c, etc. (collectively or generically referred to as processor(s) 621 and/or as processing device(s) 621). In aspects of the present disclosure, each processor 621 can include a reduced instruction set computer (RISC) microprocessor. Processors 621 are coupled to a system memory 622 and/or various other components via a system bus 633. The system memory 622 can include one or more temporary and/or persistent memory devices, such as a random access memory (RAM) 623, a read-only memory (ROM) 624, and/or the like, including combinations and/or multiples thereof. The system bus 633 may include a basic input/output system (BIOS), which controls certain basic functions of processing system 600.

Further depicted are an input/output (I/O) adapter 627 and a network adapter 626 coupled to system bus 633. I/O adapter 627 may be a small computer system interface (SCSI) adapter that communicates with a hard disk 635 and/or a storage device 636 or any other similar component. I/O adapter 627, hard disk 635, and storage device 636 are collectively referred to herein as mass storage 634. Operating system 640 for execution on processing system 600 may be stored in mass storage 634. The network adapter 626 interconnects system bus 633 with an outside network 638 enabling processing system 600 to communicate with other such systems.

A display (e.g., a display monitor) 639 is connected to system bus 633 by display adapter 632, which may include a graphics adapter to improve the performance of graphics intensive applications and a video controller. In one aspect of the present disclosure, adapters 626, 627, and/or 632 may be connected to one or more I/O buses that are connected to system bus 633 via an intermediate bus bridge (not shown). Suitable I/O buses for connecting peripheral devices such as hard disk controllers, network adapters, and graphics adapters typically include common protocols, such as the Peripheral Component Interconnect (PCI). Additional input/output devices are shown as connected to system bus 633 via user interface adapter 628 and display adapter 632. A keyboard 629, mouse 630, and speaker 631 may be interconnected to system bus 633 via user interface adapter 628, which may include, for example, a Super I/O chip integrating multiple device adapters into a single integrated circuit.

In some aspects of the present disclosure, processing system 600 includes a graphics processing unit (GPU) 637. Graphics processing unit 637 is a specialized electronic circuit designed to manipulate and alter memory to accelerate the creation of images in a frame buffer intended for output to a display. In general, graphics processing unit 637 is very efficient at manipulating computer graphics and image processing and has a highly parallel structure that makes it more effective than general-purpose CPUs for algorithms where processing of large blocks of data is done in parallel.

Thus, as configured herein, processing system 600 includes processing capability in the form of processors 621, storage capability including the system memory 622 and mass storage 634, input means such as keyboard 625 and mouse 630, and output capability including speaker 631 and display 639. In some aspects of the present disclosure, a portion of system memory 622 and mass storage 634 collectively store the operating system 640 to coordinate the functions of the various components shown in processing system 600.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A computer-implemented method comprising:
detecting a start of a constant voltage operation phase of a battery of a vehicle;
collecting current information and voltage information about the battery;
monitoring a health indicator for the battery based at least in part on the current information;
determining whether the battery is in a healthy state or a fault state by determining whether the health indicator is within an acceptable range; and
responsive to determining that the battery is in the fault state, implementing a corrective action for the battery.

2. The computer-implemented method of claim 1, wherein the health indicator is based at least in part on a slope of a line fit to a natural log of current of the battery, indicated by the current information.

3. The computer-implemented method of claim 1, wherein the health indicator is based at least in part on a coefficient of determination of a line fit to a natural log of current of the battery, indicated by the current information.

4. The computer-implemented method of claim 1, wherein collecting the current information and the voltage information about the battery is performed while the battery is in the constant voltage operation phase.

5. The computer-implemented method of claim 1, wherein the collecting terminates responsive to determining that current of the battery, indicated by the current information, reaches a minimum current level.

6. The computer-implemented method of claim 1, wherein the corrective action is at least one of repairing the battery, replacing the battery, correcting an electrolyte leak in the battery, redesigning the battery, and adjusting a manufacturing process for manufacturing other batteries.

7. The computer-implemented method of claim 1, wherein the fault state is a loss of active material fault.

8. The computer-implemented method of claim 1, wherein the fault state is an electrolyte fault.

9. A vehicle comprising:
a battery; and
a processing system, the processing system comprising:
a memory comprising computer readable instructions; and
a processing device for executing the computer readable instructions, the computer readable instructions controlling the processing device to perform operations comprising:
detecting a start of a constant voltage operation phase of the battery of the vehicle;
collecting current information and voltage information about the battery;
monitoring a health indicator for the battery based at least in part on the current information;
determining whether the battery is in a healthy state or a fault state by determining whether the health indicator for the battery is within an acceptable range; and
responsive to determining that the battery is in the fault state, implementing a corrective action for the battery.

10. The vehicle of claim 9, wherein the health indicator is based at least in part on a slope of a line fit to a natural log of current of the battery, indicated by the current information.

11. The vehicle of claim 9, wherein the health indicator is based at least in part on a coefficient of determination of a line fit to a natural log of current of the battery, indicated by the current information.

12. The vehicle of claim 9, wherein collecting the current information and the voltage information about the battery is performed while the battery is in the constant voltage operation phase.

13. The vehicle of claim 9, wherein the collecting terminates responsive to determining that current of the battery, indicated by the current information, reaches a minimum current level.

14. The vehicle of claim 9, wherein the corrective action is at least one of repairing the battery, replacing the battery, correcting an electrolyte leak in the battery, redesigning the battery, and adjusting a manufacturing process for manufacturing other batteries.

15. The vehicle of claim 9, wherein the fault state is a loss of active material fault.

16. The vehicle of claim 9, wherein the fault state is an electrolyte fault.

17. A computer program product comprising a computer readable storage medium having program instructions embodied therewith, the program instructions executable by at least one processor to cause the at least one processor to perform operations comprising:
detecting a start of a constant voltage operation phase of a battery of a vehicle;
collecting current information and voltage information about the battery;
monitoring a health indicator for the battery based at least in part on the current information;
determining whether the battery is in a healthy state or a fault state by determining whether the health indicator is within an acceptable range; and
responsive to determining that the battery is in the fault state, implementing a corrective action for the battery.

18. The computer program product of claim 17, wherein the health indicator is based at least in part on a slope of a line fit to a natural log of current of the battery, indicated by the current information.

19. The computer program product of claim 17, wherein the health indicator is based at least in part on a coefficient of determination of a line fit to a natural log of current of the battery, indicated by the current information.

20. The computer program product of claim 17, wherein the fault state is one of a loss of active material fault or an electrolyte fault.
